(19) United States
(12) Patent Application Publication
(10) Pub. No.: US 2004/0018662 A1
(43) Pub. Date: Jan. 29, 2004

(54) Method of manufacturing a semiconductor device

(76) Inventor: Toshinori Goto, Miyazaki (JP)

Correspondence Address: RABIN & Berdo, PC, 1101 14TH STREET, NW, SUITE 500, WASHINGTON, DC, 20005, US

(21) Appl. No.: 10/619,003

(22) Filed: Jul. 15, 2003

Related U.S. Application Data
(63) Continuation of application No. 09/939,801, filed on Aug. 28, 2001, now abandoned.

(30) Foreign Application Priority Data
Aug. 29, 2000 (JP) 258788/2000

(51) Int. Cl. H01L 21/48; H01L 23/52

(52) U.S. Cl. 438/109; 257/685; 257/686; 257/777

(57) ABSTRACT

A semiconductor device according to the present invention includes a first semiconductor chip having a semiconductor substrate area and a transistor forming area, at least one first electrode formed on the periphery of the semiconductor substrate area, at least one second electrode formed on the periphery of the transistor forming area, a second semiconductor chip mounted on the semiconductor substrate area of the first semiconductor chip, at least one third electrode formed on the second semiconductor chip, a plurality of leads disposed around the first semiconductor chip, at least one first metal wire which connects the first electrode of the first semiconductor chip and the third electrode of the second semiconductor chip, at least one second metal wire which connects the second electrode of the first semiconductor chip and each of the leads, and an encapsulating resin for sealing the first and second semiconductor chips, the first and second metal wires and some of the leads.

### BACKGROUND OF THE INVENTION

1. Field of the Invention

The present invention relates to a semiconductor device wherein a plurality of semiconductor chips are stacked on one another and sealed with a resin. “This application is a counterpart application of Japanese Application Serial Number 258788/2000, filed Aug. 29, 2000, the subject matter of which is incorporated herein by reference.”

2. Description of the Related Art

A semiconductor device of a type wherein a plurality of laminated semiconductor elements are sealed with a resin, has heretofore been called a “Multi Chip Package (MCP)”. One example of a sectional structure of the MCP is shown in FIG. 4. In FIG. 4, an MCP 400 has such a structure as described below. A first semiconductor chip 403 is placed on a die pad 401 as a base chip. A second semiconductor chip 405 smaller than the first semiconductor chip 403 is placed over the first semiconductor chip 403 with an adhesive resin 404 interposed there between. Electrodes of the second semiconductor chip 405 are connected to the first semiconductor chip 403 by bonding wires 409. Electrodes of the first semiconductor chip 403 are connected to their corresponding leads 402 by bonding wires 410. Further, the first and second semiconductor chips 403 and 405, the bonding wires 409 and 410, the die pad 401 and some of the leads 402 are sealed with an encapsulating resin 408.

Thus, in the semiconductor device wherein the plurality of semiconductor chips are vertically stacked on one another inside one package, the use of materials high in dissipation as those for the encapsulating resin 408 constituting the package and the die pad 401 has been considered as measures against the radiation of the MCP with a view toward controlling a mutual adverse effect on the first and second semiconductor chips 403 and 405 due to heat generated therefrom during operation thereof.

However, such an MCP as described above has a possibility that when power used up or consumed by the first and second semiconductor chips 403 and 405 increase even if the countermeasures against the radiation have been taken by using the materials for the encapsulating resin constituting the package and the die pad as those high in dissipation, the semiconductor chips per se will malfunction due to their self-heating, thereby degrading the reliability of their functions.

Thus, control of a rise in surface temperature of each of the semiconductor chips per se due to self-heating of the semiconductor chips placed inside the package has been desirable for the MCP referred to above.

### SUMMARY OF THE INVENTION

An object of the present invention is to provide a semiconductor device capable of controlling a rise in temperature, which occurs inside a package due to heat (self-heating) radiated from a semiconductor chip.

In order to achieve the above object, a semiconductor device according to the present invention comprises a first semiconductor chip having a semiconductor substrate area and a transistor forming area, at least one first electrode formed on the periphery of the semiconductor substrate area, at least one second electrode formed on the periphery of the transistor forming area, a second semiconductor chip mounted on the semiconductor substrate area of the first semiconductor chip, at least one third electrode formed on the second semiconductor chip, a plurality of leads disposed around the first semiconductor chip, at least one first metal wire which connects the first electrode of the first semiconductor chip and the third electrode of the second semiconductor chip, at least one second metal wire which connects the second electrode of the first semiconductor chip and each of the leads, and an encapsulating resin for sealing the first and second semiconductor chips, the first and second metal wires and some of the leads.

Further, in order to achieve the above object, another semiconductor device according to the present invention comprises a first semiconductor chip having a first area and a second area which surrounds the first area, at least one first electrode formed on the periphery of the first area, at least one second electrode formed on the periphery of the second area, a second semiconductor chip mounted on the first area of the first semiconductor chip, at least one third electrode formed on the second semiconductor chip, a plurality of leads disposed around the first semiconductor chip, at least one first metal wire which connects the first electrode of the first semiconductor chip and the third electrode of the second semiconductor chip, at least one second metal wire which connects the second electrode of the first semiconductor chip and each of the leads, and an encapsulating resin for sealing the first and second semiconductor chips, the first and second metal wires and some of the leads.

### BRIEF DESCRIPTION OF THE DRAWINGS

While the specification concludes with claims particularly pointing out and distinctly claiming the subject matter which is regarded as the invention, it is believed that the invention, the objects and features of the invention and further objects, features and advantages thereof will be better understood from the following description taken in connection with the accompanying drawings in which:

FIG. 1 is a cross-sectional view showing a semiconductor device according to each of first and second embodiments of the present invention;

FIG. 2 is a plan view illustrating the semiconductor device according to the first embodiment of the present invention;

FIG. 3 is a plan view depicting the semiconductor device according to the second embodiment of the present invention; and

FIG. 4 is a cross-sectional view showing a conventional semiconductor device.

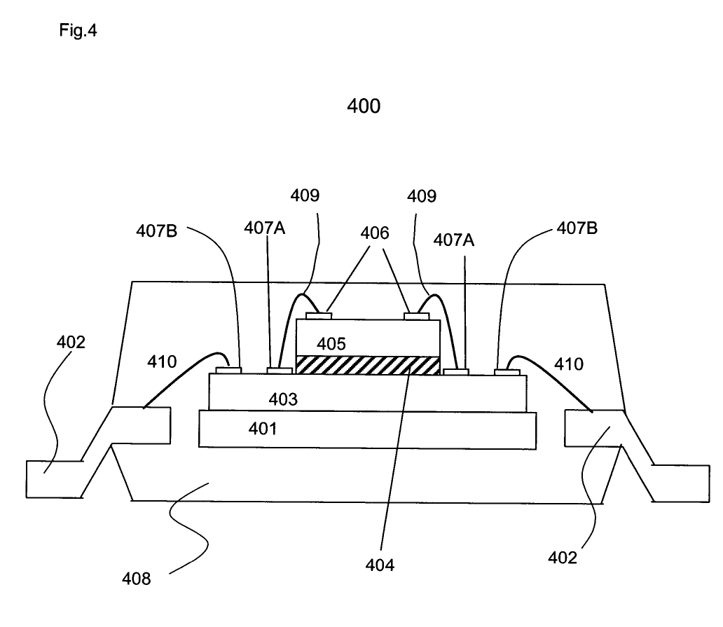

### DETAILED DESCRIPTION OF THE INVENTION

Preferred embodiments of the present invention will hereinafter be described with reference to the accompanying drawings.

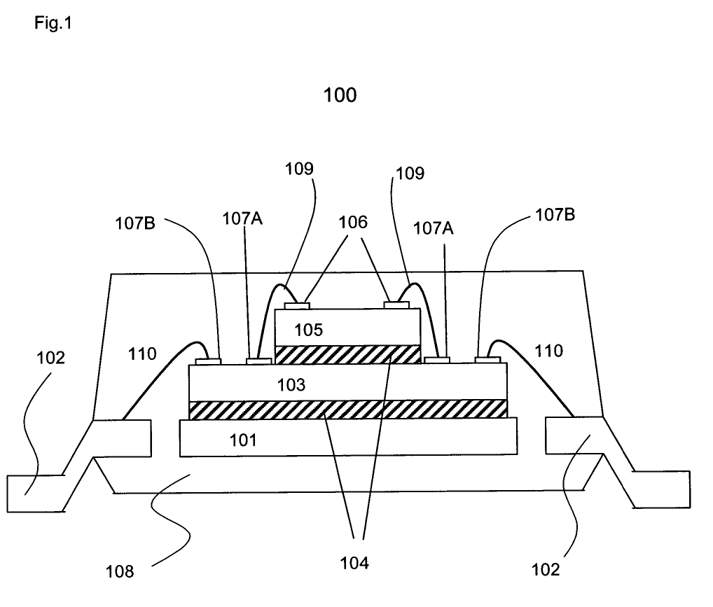

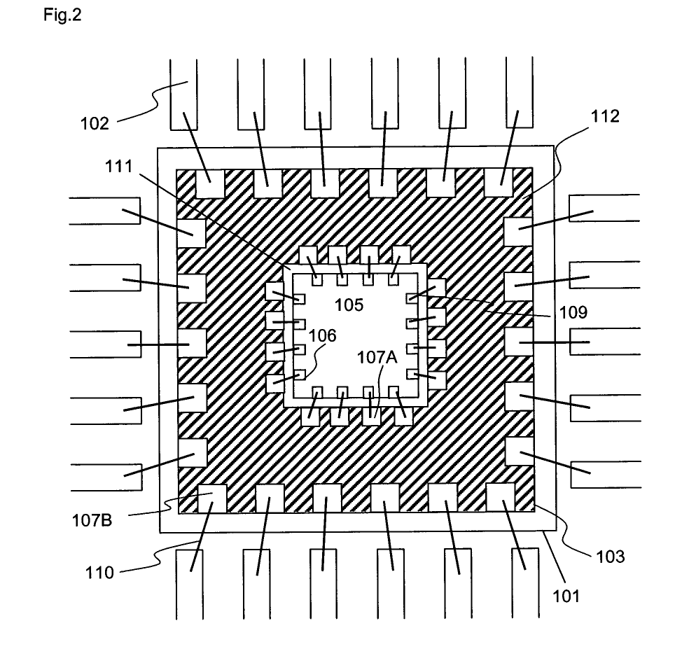

A plan view of a semiconductor device according to the first embodiment of the present invention is shown in FIG. 1. Plan views of an upper semiconductor chip and a lower semiconductor chip stacked on each other, which are employed in the first embodiment of the present invention, are respectively shown in FIG. 2. As shown in FIG. 1, a lower semiconductor chip 103 is mounted over a die pad 101 with an adhesive layer 104 interposed there between. As shown in FIG. 2 here, for example, a substantially central area of the lower semiconductor chip 103 serves as a semiconductor substrate area 111 with no MOS (Metal Oxide Semiconductor) transistor formed therein. A peripheral area 112 of the semiconductor substrate area 111 serves as an area in which a MOS transistor is formed. An upper semiconductor chip 105 is placed over the semiconductor substrate area 111 of the lower semiconductor chip 103, i.e., an area of the lower semiconductor chip 103, which is free of the formation of elements which generate heat upon operation of the MOS transistor or the like, with an adhesive layer 104 interposed there between. The die pad 101, lower semiconductor chip 103 and upper semiconductor chip 105 are sealed with an encapsulating resin 108. A plurality of electrode pads 106, each of which is supplied with an input signal, a source potential or a ground potential, or outputs an output signal therefrom, are formed on the surface of the upper semiconductor chip 105 along the periphery of the upper semiconductor chip 105.

On the other hand, a plurality of electrode pads 107A are formed on the peripheral area 112 along the periphery of the semiconductor substrate area 111 of the lower semiconductor chip 103 so as to be electrically connected to the upper semiconductor chip 105. A plurality of electrode pads 107B are formed on the peripheral area 112 of the lower semiconductor chip 103 along the outer periphery of the peripheral area 112 of the lower semiconductor chip 103 so that the lower semiconductor chip 103 or the upper semiconductor chip 105 and leads 102 are electrically connected to one another.

As shown in FIG. 1, a plurality of electrodes 106 of the upper semiconductor chip 105 and a plurality of electrodes 107A of the lower semiconductor chip 103 are electrically connected to one another by metal wires 109. The plurality of electrode pads 107B of the lower semiconductor chip 103 and the plurality of leads are electrically connected to one another by metal wires 110. Thus, signals inputted from the outside of the semiconductor device 100 are respectively transmitted to the lower semiconductor chip 103 through the metal wires 110. After the input signals have been inputted to the lower semiconductor chip 103, they are transmitted to the upper semiconductor chip 105 through the MOS transistor, electrode pads 107A and metal wires 109 formed on the peripheral area 112 of the lower semiconductor chip 103. On the other hand, signals outputted from the lower semiconductor chip 103 to the outside of the semiconductor device 100 are transmitted via the metal wires 110 and the leads 102, whereas signals outputted from the upper semiconductor chip 105 to the outside of the semiconductor device 100 are respectively transmitted via the metal wires 109, the MOS transistor, electrode pads 107B, and metal wires 110 formed on the peripheral area 112 of the lower semiconductor chip 103, and the leads 102.

Now, the electrode pads 106 of the upper semiconductor chip 105 and the electrode pads 107B of the lower semiconductor chip 103 may electrically be connected to one another by their corresponding metal wires. The electrode pads 107B of the lower semiconductor chip 103 and the leads 102 may electrically be connected to one another by their corresponding metal wires 110. As compared with the case in which the electrode pads 106 of the upper semiconductor chip 105 are directly connected to their corresponding leads 102 by means of the metal wires, such connections as described above make it possible to lower the possibility that when the lower semiconductor chip 103 and the upper semiconductor chip 105 are sealed with the encapsulating resin 108, the metal wires will be caused to flow, thereby contacting adjacent metal wires.

If the semiconductor substrate area 111 of the lower semiconductor chip 103 and the upper semiconductor chip 105 are supposed to be substantially identical to each other in the above-described semiconductor device, then the curvature of each of the metal wires 109 for electrically connecting the lower semiconductor chip 103 and the upper semiconductor chip 105 increases, thus resulting in an increase in stress applied to the metal wire 109, thereby causing the potential for breaking of each wire. In the semiconductor device according to the present invention, however, the semiconductor substrate area 111 of the lower semiconductor chip 103 serves as an area slightly larger than the upper semiconductor chip 105 mounted thereon. It is therefore possible to restrain stress applied to the metal wires 109 which connect between the plurality of electrode pads 106 of the upper semiconductor chip 105 and the plurality of electrode pads 107A of the lower semiconductor chip 103.

According to the semiconductor device according to the first embodiment of the present invention as described above, the upper semiconductor chip 105 mounted over the lower semiconductor chip 103 is placed on the semiconductor substrate area 111 of the lower semiconductor chip 103, i.e., the area free of the formation of the elements accompanied with the heat generated upon operation of the MOS transistor and the like in the semiconductor device wherein the two semiconductor chips are stacked on each other. Therefore, the transfer of heat from the upper semiconductor chip 105 to the lower semiconductor chip 103 or vice versa is restrained upon the operation of the semiconductor device. As a result, a rise in temperature inside the semiconductor device at its operation can effectively be restrained.

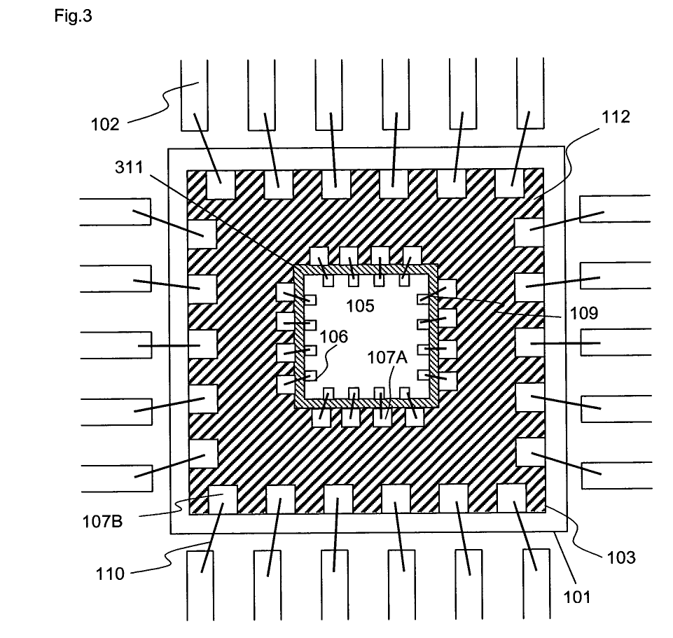

A plan view of a semiconductor device according to a second embodiment of the present invention is shown in FIG. 3. A cross-sectional view illustrative of an upper semiconductor chip and a lower semiconductor chip stacked on each other, which are employed in the second embodiment of the present invention, is similar to that illustrative of the upper semiconductor chip and the lower semiconductor chip employed in the first embodiment shown in FIG. 1. The second embodiment is effective for the manufacture of a microcontroller used as a flash ROM (Read Only Memory) version in particular.

As shown in FIG. 1, a lower semiconductor chip 103 is mounted over a die pad 101 with an adhesive layer 104 interposed there between. The lower semiconductor chip 103 functions as a microcontroller used as a mask ROM version. In the lower semiconductor chip 103 as shown in FIG. 3, a transistor having the function of a mask ROM is formed in a substantially central area 311 thereof, for example, and a MOS transistor for serving as the microcontroller, is formed in a peripheral area 112 of a semiconductor substrate area 311. An upper semiconductor chip 105 having a function of a flash memory is placed over the central area 311 of the lower semiconductor chip 103, i.e., a mask ROM-formed area of the lower semiconductor chip 103 with an adhesive layer 104 interposed there between.

The die pad 101, lower semiconductor chip 103 and upper semiconductor chip 105 are sealed with an encapsulating resin 108. A plurality of electrode pads 106, each of which is supplied with an input signal, a source potential or a ground potential, or outputs an output signal therefrom, are formed on the surface of the upper semiconductor chip 105 along the periphery of the upper semiconductor chip 105.

On the other hand, a plurality of electrode pads 107A are formed on the peripheral area 112 along the periphery of the central area 311 of the lower semiconductor chip 103 so as to be electrically connected to the upper semiconductor chip 105. A plurality of electrode pads 107B are formed on the peripheral area 112 of the lower semiconductor chip 103 along the outer periphery of the peripheral area 112 thereof so that the lower semiconductor chip 103 or the upper semiconductor chip 105 and leads 102 are electrically connected to one another.

As shown in FIG. 1, a plurality of electrodes 106 of the upper semiconductor chip 105 and a plurality of electrodes 107A of the lower semiconductor chip 103 are electrically connected to one another by metal wires 109. The plurality of electrode pads 107B of the lower semiconductor chip 103 and the plurality of leads are electrically connected to one another by metal wires 110. Thus, signals inputted from the outside of the semiconductor device 100 are respectively transmitted to the lower semiconductor chip 103 through the metal wires 110. After the input signals have been inputted to the lower semiconductor chip 103, they are transmitted to the upper semiconductor chip 105 through the MOS transistor, electrode pads 107A and metal wires 109 formed on the peripheral area 112 of the lower semiconductor chip 103. On the other hand, signals outputted from the lower semiconductor chip 103 to the outside of the semiconductor device 100 are transmitted via the metal wires 110 and the leads 102, whereas signals outputted from the upper semiconductor chip 105 to the outside of the semiconductor device 100 are respectively transmitted via the metal wires 109, the MOS transistor, electrode pads 107B and metal wires 110 formed on the peripheral area 112 of the lower semiconductor chip 103, and the leads 102.

Now, the electrode pads 106 of the upper semiconductor chip 105 and the electrode pads 107B of the lower semiconductor chip 103 may electrically be connected to one another by their corresponding metal wires. The electrode pads 107B of the lower semiconductor chip 103 and the leads 102 may electrically be connected to one another by their corresponding metal wires 110. As compared with the case in which the electrode pads 106 of the upper semiconductor chip 105 are directly connected to their corresponding leads 102 by means of the metal wires, such connections as described above make it possible to lower the possibility that when the lower semiconductor chip 103 and the upper semiconductor chip 105 are sealed with the encapsulating resin 108, the metal wires will be caused to flow, thereby contacting adjacent metal wires.

If the central area 311 of the lower semiconductor chip 103 and the upper semiconductor chip 105 are supposed to be substantially identical to each other in the above-described semiconductor device, then the curvature of each of the metal wires 109 for electrically connecting the lower semiconductor chip 103 and the upper semiconductor chip 105 increases, thus resulting in an increase in stress applied to the metal wire 109, thereby causing the potential for breaking of each wire. In the semiconductor device according to the present invention, however, the central area 311 of the lower semiconductor chip 103 serves as an area slightly larger than the upper semiconductor chip 105 mounted thereon. It is therefore possible to restrain stress applied to the metal wires 109 which connect between the plurality of electrode pads 106 of the upper semiconductor chip 105 and the plurality of electrode pads 107A of the lower semiconductor chip 103.

According to the semiconductor device according to the second embodiment of the present invention as described above, the upper semiconductor chip 105 having the function of the flash memory, which is mounted over the lower semiconductor chip 103, is placed on the central area 311 of the lower semiconductor chip 103, i.e., the area in which the mask ROM is formed, in the semiconductor device wherein the two semiconductor chips are stacked on each other. Therefore, a flash ROM-version type microcontroller can be implemented which is capable of retraining or controlling the influence of the transfer of heat from the lower semiconductor chip to the upper semiconductor chip.

While the present invention has been described with reference to the illustrative embodiments, this description is not intended to be construed in a limiting sense. Various modifications of the illustrative embodiments, as well as other embodiments of the invention, will be apparent to those skilled in the art on reference to this description. It is therefore contemplated that the appended claims will cover any such modifications or embodiments as fall within the true scope of the invention.

1. A semiconductor device comprising:
a first semiconductor chip having a semiconductor substrate area and a transistor forming area;
at least one first electrode formed on the periphery of the semiconductor substrate area;
at least one second electrode formed on the periphery of the transistor forming area;
a second semiconductor chip mounted on the semiconductor substrate area of said first semiconductor chip;
at least one third electrode formed on said second semiconductor chip;
a plurality of leads disposed around said first semiconductor chip;
at least one first metal wire which connects the first electrode of said first semiconductor chip and the third electrode of said second semiconductor chip;
at least one second metal wire which connects said second electrode of said first semiconductor chip and said each lead; and
an encapsulating resin for sealing said first and second semiconductor chips, said first and second metal wires and some of said leads.

2. The semiconductor device according to claim 1, wherein the semiconductor substrate area is surrounded by the transistor forming area.

3. The semiconductor device according to claim 1, wherein the semiconductor substrate area is an approximately central area of said first semiconductor chip.

4. The semiconductor device according to claim 1, wherein the semiconductor substrate area is larger than the area of the second semiconductor chip.

5. The semiconductor device according to claim 1, wherein said third electrode of said second semiconductor chip is electrically connected to said second electrode of said first semiconductor chip through a transistor formed within the transistor forming area of said first semiconductor chip.

6. A semiconductor device comprising:
a first semiconductor chip having a first area and a second area which surrounds the first area;
at least one first electrode formed on the periphery of the first area;
at least one second electrode formed on the periphery of the second area;
a second semiconductor chip mounted on the first area of said first semiconductor chip;
at least one third electrode formed on said second semiconductor chip;
a plurality of leads disposed around said first semiconductor chip;
at least one first metal wire which connects the first electrode of said first semiconductor chip and the third electrode of said second semiconductor chip;
at least one second metal wire which connects said second electrode of said first semiconductor chip and said each lead; and
an encapsulating resin for sealing said first and second semiconductor chips, said first and second metal wires and some of said leads.

7. The semiconductor device according to claim 6, further including:
a microcontroller used as a mask ROM formed on the first area, and
wherein said second semiconductor chip serves a function of a flash memory.

8. The semiconductor device according to claim 7, wherein the first area is an approximately central area of said first semiconductor chip.

9. The semiconductor device according to claim 7, wherein the first area is larger than the area of said second semiconductor chip.

10. The semiconductor device according to claim 7, wherein said third electrode of said second semiconductor chip is electrically connected to said second electrode of said first semiconductor chip through a transistor formed within a transistor forming area of said first semiconductor chip.
